(19) United States
(12) Patent Application Publication
(10) Pub. No.: US 2003/0172874 A1
(43) Pub. Date: Sep. 18, 2003

(54) MECHANISM AND METHOD FOR SUPPORTING SUBSTRATE TO BE COATED WITH FILM

(76) Inventor: MASAO KAWAGUCHI, TAKI-GUN (JP)

Correspondence Address: EDWARDS & ANGELL, LLP, P.O. BOX 9169, BOSTON, MA, 02209, US

(21) Appl. No.: 09/470,615

(22) Filed: Dec. 22, 1999

(30) Foreign Application Priority Data
Dec. 22, 1998 (JP) P10-365310

(51) Int. Cl. C23C 16/00

(52) U.S. Cl. 118/728

(57) ABSTRACT

An object of the invention is to provide a mechanism and method for supporting a substrate to be coated with a film, which enables transporting a substrate coated with a thin film, out of a film forming apparatus without damaging the substrate or the thin film. A support mechanism is provided with a stage, a shaft member, and support pins. When the substrate is placed on the stage which is held in a horizontal state, the shaft member is rotated so that the stage is lifted up to a film forming position where a substrate bearing surface of the stage becomes a substantially vertical. After film formation has been carried out at the film forming position, an actuator is driven so as to move the support pins provided in the stage. Accordingly, cracks and chips in the substrate as well as peeling-off of the thin film can be almost completely prevented.

### BACKGROUND OF THE INVENTION

1. Field of the Invention

The present invention relates to a mechanism and method for supporting a substrate to be coated with a film, for use in liquid crystal display devices and semiconductor devices such as transistors.

2. Description of the Related Art

In Japanese Unexamined Patent Publication JP-A 8-107076 (1996), there is described a CVD (Chemical Vapor Deposition) apparatus for forming a thin film on a surface of a supported wafer. In this CVD apparatus, a susceptor is used as a wafer support mechanism. A wafer is placed on a top of the bearing surface of the susceptor which is horizontally held. When the wafer has been placed, the susceptor is angularly displaced so that the bearing surface is vertical. In this state, a thin film is formed on a top of the wafer. Wafer chuck pins are fixed to the bearing surface. The wafer chuck pins support the wafer on the bearing surface and prevent the wafer from falling due to the angular displacement of the susceptor. After the film has been formed, the susceptor is angularly displaced again so that the bearing surface is vertical. In this state, the wafer is lifted up and transported away.

In the CVD apparatus disclosed in JP-A 8-107076, because the wafer is in contact with the wafer chuck pins when the thin film is formed, thin film material may adhere to surfaces of the wafer chuck pins as well as forming the thin film on the wafer. When the wafer in this state is forcibly lifted up from the top of the susceptor to be transported out, the thin film on the wafer is pulled by the thin film adhering to the wafer chuck pins and is peeled off. Cracks, chips or the like may also be caused in the wafer itself.

### SUMMARY OF THE INVENTION

An object of the invention is to provide a mechanism and method for supporting a substrate to be coated with a thin film, which mechanism and method enables transporting the substrate coated with a thin film out of a film forming apparatus without damaging the thin film as well as the substrate.

The invention provides a mechanism for supporting a substrate to be coated with a film, which mechanism is used in a film forming apparatus, comprising:

a stage for receiving a substrate which has been transported into the film forming apparatus to form a film on the substrate;

a shaft member for angularly displacing the stage bearing the substrate from a substrate receiving position at which the stage received the substrate, to a film forming position at which a substrate bearing surface of the stage is vertical or substantially vertical;

a plurality of support members which are provided so as to protrude from the substrate bearing surface of the stage, for supporting an end surface of the substrate, which faces downwards, when the stage is angularly displaced to the film forming position; and

moving means for moving the support members.

According to the invention, since the support members, which support an end surface of a substrate to be coated with a film, are movable during film formation, peeling-off of the thin film which has been formed on the substrate, as well as cracks and chips in the substrate coated with the thin film can be almost completely prevented by moving the support members before transporting the substrate out of the film forming apparatus after formation of the film.

In the invention it is preferable that the moving means causes the support members to move in parallel in one direction of three dimensional directions on the stage or causes the support members to rotationally move on the stage.

According to the invention, since the support members are moved in parallel or moved rotationally, peeling-off of the thin film formed on the substrate, as well as cracks and chips in the substrate can be almost completely prevented by moving the support members before transporting the substrate out of the film forming apparatus after formation of the film.

In the invention it is preferable that the moving means moves the support members towards or away from the shaft member.

According to the invention, since the direction of movement of the support members is a direction towards or away from the shaft member, the support members can be prevented from rubbing against the end surface of the substrate on which a film has been formed when the support members are moved. Accordingly, dust caused by rubbing can be prevented from being contained in the thin film, with the result that the quality of the thin film is improved.

In the invention it is preferable that the moving means is connected together with a plurality of the support members and moves the plurality of support members in one operation.

According to the invention, the plurality of support members can be moved in one operation by a single moving means, which makes the structure of the support mechanism simple.

In the invention it is preferable that a plurality of the moving means are provided to respectively connect with the plurality of support members to move the plurality of support members independently.

According to the invention, the plurality of support members can be moved independently by the moving means respectively provided for the plurality of support members, so that, for example, the respective support members can move in different manners.

In the invention it is preferable that the moving means is an actuator.

According to the invention, the movement of the support members can be achieved by an actuator having a simple structure.

In the invention it is preferable that each of the plurality of support members is formed in a columnar shape.

According to the invention, since the support members are formed in a columnar shape, the areas of the surfaces of the support members which come into contact with the end surface of the substrate to be coated with a film can be decreased. Accordingly, the thin film which has been formed on the substrate tends not to adhere to the support members and peeling-off of the thin film from the substrate, as well as cracks and chips in the substrate can be almost completely prevented.

In the invention it is preferable that the substrate is a glass substrate or a semiconductor wafer.

According to the invention, when a thin film is formed on a glass substrate or a semiconductor wafer, peeling-off of the thin film which has been formed on the glass substrate or the semiconductor wafer, as well as cracks and chips in the glass substrate or the semiconductor wafer can be almost completely prevented.

Moreover, the invention provides a method for supporting a substrate to be coated with a film, which method is used in a film forming apparatus, comprising:

a step of placing a substrate to be coated with a film, which substrate has been transported into the film forming apparatus, on a stage movably provided with a plurality of support members;

a step of angularly displacing the stage on which the substrate is placed, from a substrate receiving position at which the substrate has been received by the stage, to a film forming position at which a substrate bearing surface of the stage is vertical or substantially vertical and at which an end surface of the substrate is supported from thereunder by the support members;

a step of angularly displacing the stage from the film forming position back to the substrate receiving position, after film formation;

a step of moving the support members after the stage has returned to the film placing position; and

transporting the substrate to be coated with a film, out of the stage of the film forming apparatus, after the movement of the support members.

According to the invention, since the support members are moved before transporting the substrate out of the film formation apparatus after the completion of film formation on the substrate, peeling-off of the thin film formed on the substrate, as well as cracks and chips in the substrate can be almost completely prevented.

In the invention it is preferable that in the step of moving the support members, the support members are moved in parallel to one direction of three dimensional directions on the stage or are rotationally moved on the stage.

According to the invention, because the support members are moved in parallel or rotationally moved, peeling-off of the thin film formed on the substrate, as well as cracks and chips in the substrate can be almost completely prevented.

In the invention it is preferable that in the step of moving the support members, the support members are moved in a direction towards or away from the shaft member for angularly displacing the stage.

According to the invention, since the direction of movement of the support members is a direction towards or away from the shaft member, the support members can be prevented from rubbing against the end surface of the substrate on which a film has been formed, when the support members are moved. Accordingly, dusts caused by rubbing can be prevented from being contained in the thin film, thereby enabling the quality of the thin film to be improved.

In the invention it is preferable that the substrate is a glass substrate or a semiconductor wafer.

According to the invention, when the thin film is formed on a glass substrate or a semiconductor wafer, peeling-off of the thin film which has been formed on the glass substrate or the semiconductor wafer, as well as cracks and chips in the glass substrate or the semiconductor wafer can be almost completely prevented.

### BRIEF DESCRIPTION OF THE DRAWINGS

Other and further objects, features, and advantages of the invention will be more explicit from the following detailed description taken with reference to the drawings wherein:

FIG. 1 is a view showing a film forming apparatus 10 which is an embodiment of the invention;

FIG. 2 is a perspective view showing a support mechanism 20 of a film forming apparatus 10; and

FIG. 3 is a side view showing the support mechanism 20 of the film forming apparatus 10.

### DETAILED DESCRIPTION OF THE PREFERRED EMBODIMENTS

Now referring to the drawings, preferred embodiments of the invention are described below.

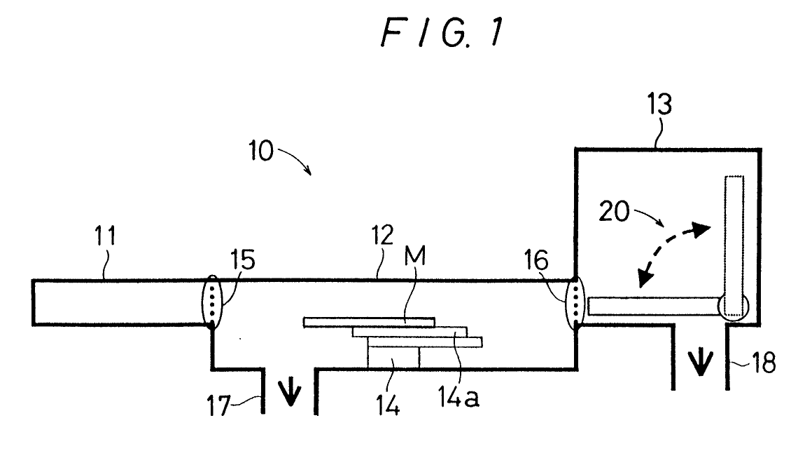

FIG. 1 is a view showing a film forming apparatus 10 which is an embodiment of the invention. The film forming apparatus 10 comprises a load lock chamber 11 which can be sealed, a transport chamber 12, and a film forming chamber 13. The load lock chamber 11 is a passage through which a substrate M to be coated with a film is transported into the film forming apparatus. The transport chamber 12 is connected to the load lock chamber 11 and has a vacuum robot 14 for transporting the substrate M in a vacuum. The film forming chamber 13 is connected to the transportance chamber 12 and has a support mechanism 20 for supporting the substrate M.

A gate valve 15 is provided between the load lock chamber 11 and the transport chamber 12, and a gate valve 16 is provided between the transport chamber 12 and the film forming chamber 13. Exhaust pipes 17 and 18 are respectively provided in the transport chamber 12 and film forming chamber 13.

In the film forming apparatus 10, firstly, a substrate M is fed into the interior of the load lock chamber 11 from one end thereof. The load lock chamber 11, the transport chamber 12, and the film forming chamber 13 are then sealed. The gate valves 15 and 16 are then closed and gas inside is exhausted via the exhaust pipes 17 and 18. A vacuum is thus created inside the transport chamber 12 and the film forming chamber 13.

When the substrate M inside the load lock chamber 11 is transported to the gate valve 15, the gate valve 15 opens. The vacuum robot 14 in the transport chamber 12 extends an arm 14a and receives the substrate M to transport the substrate M to the gate valve 16. When the vacuum robot 14 receives the substrate M, the gate valve 15 is closed. When the substrate M has been transported up to the gate valve 16, after the substrate M waits for the transport chamber 12 to be placed in a vacuum once more through the exhaust of gas from the exhaust pipe 17, the gate valve 16 is opened, and the vacuum robot 14 again extends an arm and transfers the substrate M onto the support mechanism 20 inside the film forming chamber 13. When the substrate M has been transferred, the gate valve 16 is closed.

After film formation has been completed inside the film forming chamber 13, the substrate M is fed back in reverse along the transporting path and is taken out from the load lock chamber 11.

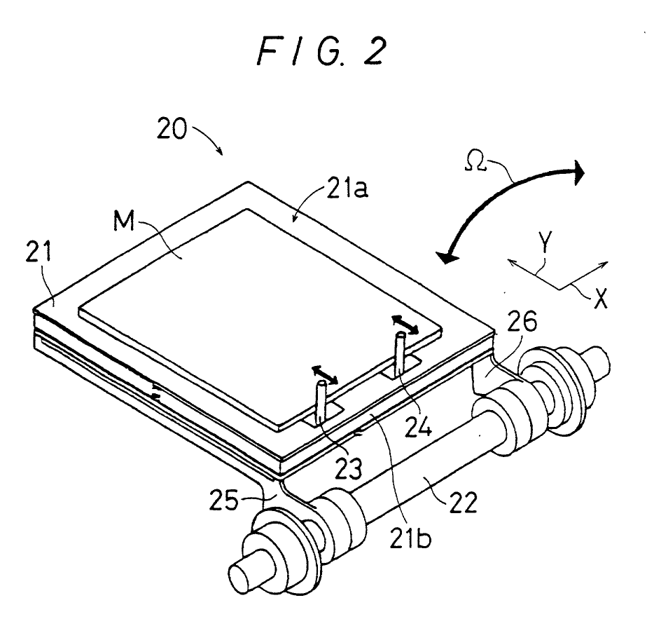

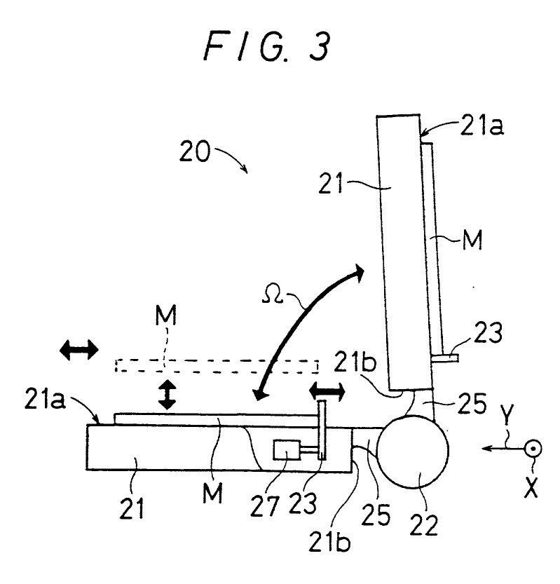

FIG. 2 is a perspective view showing the support mechanism 20 of the film forming apparatus 10 and FIG. 3 is a side view of the same. The support mechanism 20 has a stage 21, a shaft member 22, support pins 23, 24 and the like. The stage 21 is constituted with a rectangular plate-shaped member and has a flat substrate bearing surface 21a on which the substrate M is placed. Directions parallel to two adjacent sides of the stage 21 are taken as direction X and direction Y.

The shaft member 22 is disposed at a predetermined distance from the stage 21 facing an end surface 21b of the stage 21 and extends in the direction X. The stage 21 and the shaft member 22 are linked by link members 25 and 26. The shaft member 22 is rotatable in directions Ω about a longitudinal axis thereof. After the substrate M on which film formation has been completed has been transported out by the vacuum robot 14 and while the receipt of the next substrate M by the vacuum robot 14 is being awaited, the shaft member 22 supports the stage 21 in a horizontal state. A position where the stage 21 is being supported in a horizontal state to receive the substrate is hereafter called a substrate receiving position. When film formation is performed, the shaft member 22 rotates to angularly displace the stage 21 up to a film forming position where the substrate bearing surface 21a becomes parallel with a vertical or substantially vertical direction.

The support pins 23, 24 are provided at an end portion of the substrate bearing surface 21a so as to protrude upright from the substrate bearing surface 21a. The support pins 23, 24 can support the end surface of the substrate M from beneath even when the stage 21 is lifted up to the film forming position by rotation of the shaft member 22. By carrying out film formation in this way with the substrate M which has been supported parallel with a vertical or substantially vertical direction, particles and the like can be prevented from falling onto the formed thin film.

The support pins 23, 24 are each formed in a columnar shape and have a small area of contact with the end surface of the substrate M. Accordingly, the thin film which has been formed on the substrate M tends not to adhere to the support pins 23, 24, and peeling-off of the thin film from the substrate M and cracks or chips in the substrate M can be prevented.

The support pins 23, 24 are also both connected to an actuator 27 and can move in the direction Y, namely in a direction in which the pins 23, 24 they either move towards or away from the shaft member 22. After film formation, the support pins 23, 24, contacting with an end surface of the substrate M can be separated therefrom without damaging the substrate M or the thin film which has been formed thereon. The movement of the support pins 23, 24 may be a movement where they move towards the shaft member 22 in the direction Y, a reciprocating motion where after this towards movement they move away from the shaft member 22, or a cyclic oscillating movement.

Note that the support pins 23, 24 are moved by the actuator 27, but dedicated actuators may be individually provided for the respective support pin 23, 24 so as to move the support pins independently of each other.

Next, a support method for a substrate M using the support mechanism 10 shown in FIG. 2 will be explained. Firstly, the substrate M is transported into the film forming chamber 13 and is placed on the stage 21. Next, the stage 21 is angularly displaced from the substrate receiving position at which the substrate M is placed on the stage 21, to the film forming position at which the substrate bearing surface 21a of the stage 21 becomes vertical or substantially vertical. The end surface of the substrate M is thus supported from beneath by the support pins 23, 24.

After film formation, the stage 21 is angularly displaced from the film forming position back to the substrate receiving position. Once the stage 21 has returned to the substrate receiving position from the film forming position, the actuator 27 is driven so as to move the support pins 23, 24. Finally, the substrate M is lifted up and transported out from the film forming chamber 13.

Note that not only a glass substrate but also a semiconductor wafer may be used as the substrate M in the present embodiment. Moreover, the mechanism and method for supporting a substrate to be coated with a film of the invention may be applied to a film forming apparatus for forming a desired film on a glass substrate or a semiconductor wafer.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

What is claimed is:

1. A mechanism for supporting a substrate to be coated with a film, which mechanism is used in a film forming apparatus, comprising:
a stage for receiving a substrate which has been transported into the film forming apparatus to form a film on the substrate;
a shaft member for angularly displacing the stage bearing the substrate from a substrate receiving position at which the stage received the substrate, to a film forming position at which a substrate bearing surface of the stage is vertical or substantially vertical;
a plurality of support members which are provided so as to protrude from the substrate bearing surface of the stage, for supporting an end surface of the substrate, which faces downwards, when the stage is angularly displaced to the film forming position; and
moving means for moving the support members.

2. The mechanism for supporting a substrate to be coated with a film of claim 1, wherein the moving means causes the support members to move in parallel in one direction of three dimensional directions on the stage or causes the support members to rotationally move on the stage.

3. The mechanism for supporting a substrate to be coated with a film of claim 1, wherein the moving means moves the support members towards or away from the shaft member.

4. The mechanism for supporting a substrate to be coated with a film of claim 1, wherein the moving means is connected together with a plurality of the support members and moves the plurality of support members in one operation.

5. The mechanism for supporting a substrate to be coated with a film of claim 1, wherein a plurality of the moving means are provided to respectively connect with the plurality of support members to move the plurality of support members independently.

6. The mechanism for supporting a substrate to be coated with a film of claim 1, wherein the moving means is an actuator.

7. The mechanism for supporting a substrate to be coated with a film of claim 1, wherein each of the plurality of support members is formed in a columnar shape.

8. The mechanism for supporting a substrate to be coated with a film of claim 1, wherein the substrate is a glass substrate or a semiconductor wafer.

9. A method for supporting a substrate to be coated with a film, which method is used in a film forming apparatus, comprising the steps of:
placing a substrate to be coated with a film, which substrate has been transported into the film forming apparatus, on a stage movably provided with a plurality of support members;
angularly displacing the stage on which the substrate is placed, from a substrate receiving position at which the substrate has been received by the stage, to a film forming position at which a substrate bearing surface of the stage is vertical or substantially vertical and at which an end surface of the substrate is supported from thereunder by the support members;
angularly displacing the stage from the film forming position back to the substrate receiving position, after film formation;
moving the support members after the stage has returned to the film placing position; and
transporting the substrate to be coated with a film, out of the stage of the film forming apparatus, after the movement of the support members.

10. The method for supporting a substrate to be coated with a film of claim 9, wherein in the step of moving the support members, the support members are moved in parallel to one direction of three dimensional directions on the stage or are rotationally moved on the stage.

11. The method for supporting a substrate to be coated with a film of claim 9, wherein in the step of moving the support members, the support members are moved in a direction towards or away from the shaft member for angularly displacing the stage.

12. The method for supporting a substrate to be coated with a film of claim 9, wherein the substrate is a glass substrate or a semiconductor wafer.
